(19) United States
(12) Patent Application Publication
(10) Pub. No.: US 2026/0144100 A1
(43) Pub. Date: May 21, 2026

(54) SEMICONDUCTOR DEVICE AND ASSEMBLY

(71) Applicant: Intel Corporation, Santa Clara, CA (US)

(72) Inventors: Jenny Shio Yin ONG, Bayan Lepas (MY); Mouk Pio KANG, Bukit Mertajam (MY); Choon Hou LOCK, Bayan Lepas (MY); Suk Han YAP, Gelugor (MY); Bok Eng CHEAH, Gelugor (MY)

(21) Appl. No.: 18/954,572

(22) Filed: Nov. 21, 2024

(51) Int. Cl. H01L 23/538; H01L 23/367; H01L 23/495; H01L 25/16

(52) U.S. Cl. CPC H10W 70/65; H10W 40/22; H10W 70/421; H10W 70/611; H10W 90/00

(57) ABSTRACT

There may be provided a device which may include a main body. The main body may include a panel portion and a protrusion arrangement extending from the panel portion, the protrusion arrangement being non-parallel to the panel portion. The device may further include at least one power management component disposed at the panel portion of the main body. The device may further include an interconnect which may include a primary connection point and an auxiliary connection point. The primary connection point may be electrically coupled to the at least one power management component at the panel portion of the main body, while the auxiliary connection point is positioned away from the panel portion.

### BACKGROUND

Electronic devices today rely heavily on board-level implementations for various functions, such as power delivery and signal processing. These functions are typically managed by integrated circuits mounted on printed circuit boards. While this method has become standard practice, it presents certain challenges.

Power delivery lines and signal paths across printed circuit boards can encounter resistance and signal attenuation as they traverse different components, which can result in power loss, reduced energy efficiency, and potential degradation in signal quality. These issues tend to be exacerbated as devices become more complex, driven by the demand for high-speed data transfer and low-power operation.

As the market for high-performance devices expands, traditional devices increasingly struggle to meet the needs for efficient power management, low signal latency and robust interconnection.

Recognizing these limitations, there is a need for an improved device and assembly that address at least the issues identified above.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. In the following description, various aspects are described with reference to the following drawings, in which:

FIG. 1A shows a perspective view of a schematic diagram of a device mounted on a substrate, according to various aspects;

FIG. 1B shows a cross-sectional view taken along line A-A of FIG. 1A, according to various aspects;

FIG. 1C shows a cross-sectional view of the device separated from the substrate, according to various aspects;

FIG. 1D shows a cross-sectional view of the device having a bridge-interconnection-branch, according to various aspects;

FIG. 1E shows a cross-sectional view of the device having a die-interconnection-branch, according to various aspects;

FIG. 1F shows a cross-sectional view of the device having both the bridge-interconnection-branch and the die-interconnection-branch, according to various aspects;

FIG. 2A shows a perspective view of a schematic diagram of the device having at least one ventilation opening for a heat-dissipation arrangement, according to various aspects;

FIG. 2B shows a cross-sectional view taken along line B-B of FIG. 2A, according to various aspects;

FIG. 2C shows a cross-sectional view of the device having a plurality of die-receiving-spaces and a plurality of ventilation openings, according to various aspects

FIG. 3 shows a top view of a schematic diagram of a plurality of devices on the substrate, according to various aspects;

FIG. 4 shows a top view of a schematic diagram of a plurality of differently sized devices on the substrate, according to various aspects;

FIG. 5A is a flowchart depicting a process of making the device, according to various aspects;

FIG. 5B is a flowchart depicting a process of making an assembly, which incorporates the device, according to various aspects; and

FIG. 6A to FIG. 6Q show an example process of making the device and the assembly, according to various aspects.

### DETAILED DESCRIPTION

Aspects described below in the context of the apparatus are analogously valid for the respective methods, and vice versa. Furthermore, it will be understood that the aspects described below may be combined, for example, a part of one aspect may be combined with a part of another aspect.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless the context clearly indicates otherwise. Similarly, the word “or” is intended to include “and” unless the context clearly indicates otherwise.

The present disclosure generally relates to a device (e.g. a semiconductor device) which may be configured (or may serve or function) as a voltage regulator device or a voltage regulator module (VRM). According to various aspects, the device may be capable of enhancing power management in semiconductor assemblies or packages (e.g. integrated circuit assemblies) or systems.

According to various aspects, the device (e.g. VRM) may feature a modular form, allowing it to be easily stacked on a substrate (e.g. a package substrate), thereby improving assembly efficiency and integration.

In various aspects, the device may enhance power delivery efficiency by directly coupling power management components (e.g. voltage regulators) and/or passive components integrated within the device to dies on the substrate. The configuration of the device minimizes the interconnect path for power transmission, leading to overall performance. Specifically, by reducing the distance between the dies on the substrate and power management components (e.g. voltage regulators) and/or passive components integrated within the device, the device lowers resistance, resulting in improved power and thermal efficiency. This may ensure consistent and stable voltage levels may be supplied to the dies on the substrate, enhancing both the performance and reliability of the dies.

Additionally, the device, according to the various aspects, allows for a more compact and efficient form factor of an assembly that incorporates the device, reducing the need for larger board-level space. This may enhance power management while facilitating the miniaturization of assemblies, enabling the development of sleeker, more compact, and higher-performing systems.

According to the various aspects, the device may also improve thermal performance by optimizing heat dissipation from the dies. By reducing or eliminating thermal buildup around critical components, the device may help maintain stable operating temperatures, reducing the risk of overheating and thermal degradation within an assembly. This enhanced heat management contributes to overall reliability and longevity of assemblies which incorporate the device.

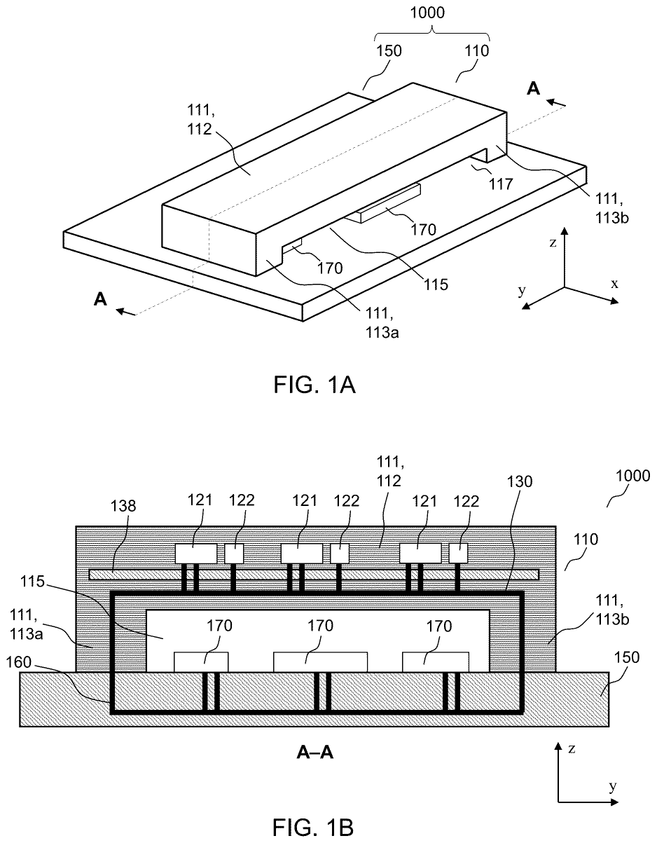

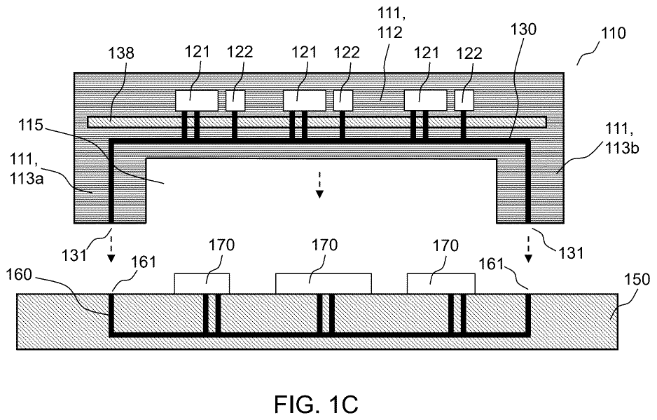

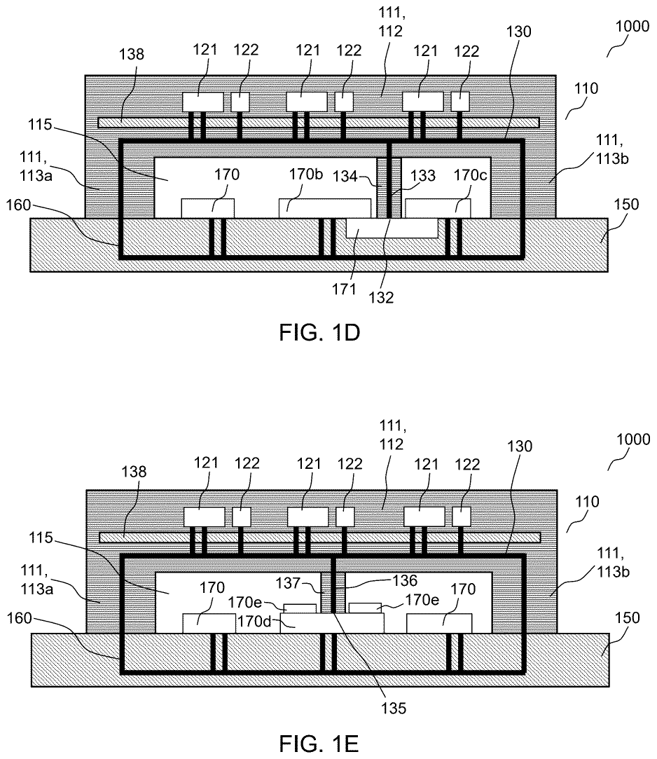

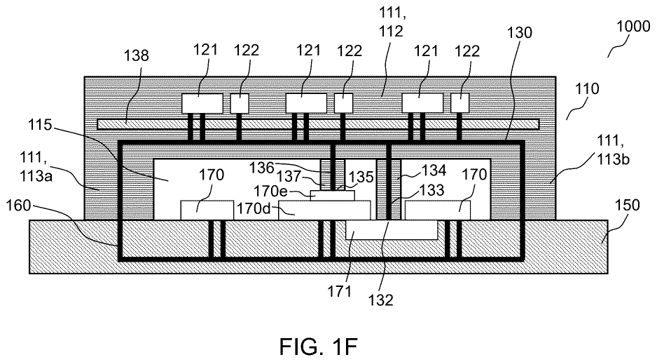

FIG. 1A shows a perspective view of a schematic diagram of a device 110 mounted on a substrate 150, according to various aspects.

FIG. 1B shows a cross-sectional view taken along line A-A of FIG. 1A, according to various aspects.

According to various aspects, there may be provided the device 110 (e.g. a semiconductor device).

With reference to FIG. 1B, according to various aspects, the device 110 may include at least one power management component 121 configured to regulate or manage electrical power (e.g. voltage, current, or overall power delivery) to operate at least one die 170. According to various aspects, this at least one die 170 may be disposed on a surface of a substrate 150 (e.g. a semiconductor substrate, a package substrate, circuit board, etc.) that may be distinct (or a discrete entity) from the device 110. As an example, according to various aspects, the at least one power management component 121 may include or may be at least one voltage regulator.

According to various aspects, the device 110 may be modular, allowing it to be selectively positioned (or disposed) at any suitable location or region on the surface of the substrate 150. Consequently, this device 110 may be selectively placed proximal (e.g. directly above) the at least one die 170 on the substrate 150, positioning the at least one power management component 121 (e.g. voltage regulator) of the device 110 close to the at least one die 170 on the substrate 150. According to various aspects, this arrangement may facilitate efficient power delivery, minimize signal integrity issues, and enhance overall functionality of an assembly (or a system) 1000 which incorporates the device 110.

According to various aspects, with reference to FIG. 1A and FIG. 1B, the device 110 may include a main body 111 that may serve as a support structure for supporting and holding various other components of the device 110. In particular, according to various aspects, the main body 111 may include a panel portion 112 (e.g. a flat or planar, or substantially flat or planar, panel portion 112) as well as a protrusion arrangement (or protrusion arrangement portion) 113 that extends or protrudes from the panel portion 112.

According to various aspects, the panel portion 112 may support or hold component(s) of the device 110, such as at least one power management component 121 and/or passive component 122, while the protrusion arrangement 113 serves as a post, leg, or stand configured to elevate the panel portion 112 over (e.g. above) the substrate 150, i.e. when the device 110 is placed on the substrate 150. Specifically, component(s) of the device 110, such as at least one power management component 121 and/or passive component 122, may be disposed at (e.g. on or within) the panel portion 112 of the main body 111 of the device 110, while the protrusion arrangement 113 supports the panel portion 112, i.e. when the device 110 is standing by its protrusion arrangement 113 on the substrate 150. As shown in FIG. 1A, the protrusion arrangement 113 may extend linearly along an “extension direction” (e.g. along the z-axis) which may be non-parallel (e.g. perpendicular or substantially perpendicular) to the panel portion 112 or to a primary or horizontal plane (not shown) of the panel portion 112. In other words, according to various aspects, the protrusion arrangement 113 may be oriented to be non-parallel (e.g. perpendicular or substantially perpendicular) relative to the panel portion 112.

As an illustration, with reference to FIG. 1A and FIG. 1B, the protrusion arrangement 113 may include a plurality of (e.g. two or more) discrete protrusion members 113a, 113b extending from a same side (e.g. a bottom side or surface) of the panel portion 112. In particular, these protrusion members 113a, 113b of the protrusion arrangement 113 may be distributed or arranged in a manner for stability and support of the panel portion 112 on the substrate 150. According to various aspects, as shown in FIG. 1A, the protrusion arrangement 113 may include at least two discrete protrusion members 113a, 113b positioned at opposite end (or edge) regions (e.g. longitudinal end or edge regions) of the panel portion 112. In various other aspects (not shown), the protrusion arrangement 113 may include a continuous protrusion member or multiple, adjoining protrusion members positioned along the entire peripheral edge region of the panel portion 112. According to various aspects, when the panel portion 112 is quadrilateral-shaped (e.g. rectangular-shaped), as illustrated in FIG. 1A, the peripheral edge region may include both the longitudinal end regions and the lateral edge regions of the panel portion 112. In various other aspects (not shown), the protrusion arrangement 113 may include multiple (e.g. four) discrete and/or spaced apart protrusion members positioned at the (e.g. four) corner regions of the panel portion 112 (e.g. a rectangular-shaped panel portion). While various aspects may be described herein with respect to the protrusion having a plurality of discrete protrusion members 113a, 113b, it is also envisaged that, in various other aspects (not shown), the protrusion arrangement 113 may include a single or sole protrusion member (e.g. positioned at a central region, within the peripheral edge region, of the panel portion 112) for supporting the panel portion 112.

According to various aspects, the plurality of protrusion members 113a, 113b may be, but are not limited to being, parallel or substantially parallel to one another.

According to various aspects, the plurality of protrusion members 113a, 113b may be, but are not limited to being, identical to one another. For example, according to various aspects, the plurality of protrusion members 113a, 113b may have a same height or thickness (along the z-axis), as measured from the panel portion 112 (e.g. from the bottom side or surface of the panel portion 112). Consequently, when the free ends of the protrusion members 113a, 113b (i.e. the ends distal or farthest from the panel portion 112) contact or engage (e.g. directly or indirectly engage) the surface of the substrate 150, the panel portion 112 may be parallel to the surface of the substrate 150. It is also envisaged that, in various other aspects (not shown), at least two of a plurality of protrusion members 113a, 113b may differ from each other (e.g. in terms of their widths along the x-axis and/or the y-axis, and/or their shapes).

As an illustration in FIG. 1A, each protrusion member 113a, 113b may have a polygonal (e.g. rectangular) transverse (e.g. horizontal) cross-sectional shape. It is also envisaged that, in various other aspects (not shown), each protrusion member 113a, 113b may have any other suitable transverse cross-sectional shape, such as a circular shape resembling or functioning as a cylindrical pillar or column. Furthermore, according to various aspects, each protrusion member 113a, 113b may have, but is not limited to having, a uniform cross-sectional area or profile, along its height or thickness (i.e. along the z-axis).

According to various aspects, a total transverse cross-sectional area of the protrusion arrangement 113 of the main body 111 may be smaller than that of the panel portion 112 of the main body 111. As a result, as shown in FIG. 1A and FIG. 1B, the (e.g. all) inner (or inward-facing) surface(s) of the protrusion arrangement 113, along with the inner (or inward-facing) surface (e.g. bottom surface) of the panel portion 112, may define and/or bound a space (e.g. a cavity, recess, pocket, or receptacle) (herein may be referred to as “die-receiving-space 115”) adapted (e.g. dimensioned, shaped and/or sized) to accommodate or receive at least one die 170 and/or various other component(s) (e.g. one or more components which may be external to the device 110 itself).

As shown in FIG. 1A and FIG. 1B, the die-receiving-space 115 may be situated between a pair of neighboring (or immediately adjacent) and spaced apart protrusion members 113a, 113b. In particular, the pair of neighboring protrusion members 113a, 113b may be aligned along a straight or substantially straight reference line or axis (e.g. lengthwise of the panel portion 112, along the y-axis). Specifically, according to various aspects, the die-receiving-space 115 may be defined by the inner (or inward-facing) surfaces of the pair of neighboring protrusion members 113a, 113b, which oppose (e.g. face or are directed toward) each other.

In various aspects, the main body 111 of the device 110 may define a single, continuous and/or uninterrupted die-receiving-space 115 adapted to accommodate one or more dies 170, as depicted in FIG. 1A.

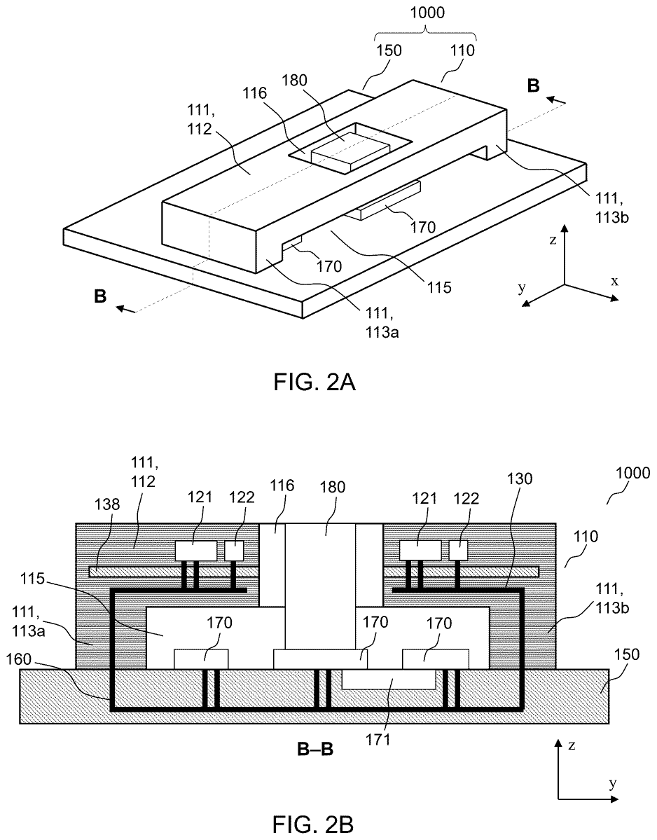

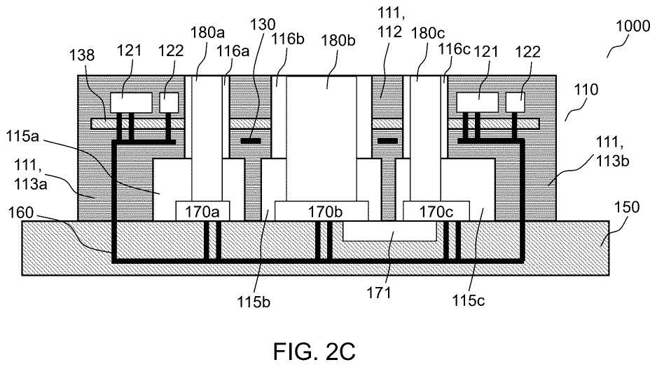

In various other aspects, the main body 111 of the device 110 may define a plurality of die-receiving-spaces 115, each die-receiving-space 115 adapted to accommodate one or more respective dies 170 (see, for example, FIG. 2C, described later). In these other aspects, the plurality of die-receiving-spaces 115 may have identical shapes and/or sizes, or may differ in shape and/or size.

As an example, according to various other aspects, when the main body 111 of the device 110 defines a plurality of die-receiving-spaces 115, at least two of the plurality of die-receiving-spaces 115 may be discrete and/or isolated from one another, with neighboring (or immediately adjacent) die-receiving-spaces 115 being partitioned by a respective protrusion member of the protrusion arrangement 113. In such a configuration, the protrusion member serving as the partition may have a same or substantially the same width as the panel portion 112 (e.g. along the x-axis).

As another example, according to various other aspects, when the main body 111 of the device 110 defines a plurality of die-receiving-spaces 115, the plurality of die-receiving-spaces 115 may be partially adjoined, with neighboring (or immediately adjacent) die-receiving-spaces 115 connected through a gap, hole, or an opening (e.g. a side opening) defined by a respective protrusion member positioned between them. For instance, the protrusion member serving as the partition may have a narrower width than the panel portion 112, thereby forming or defining an opening at one or both sides (e.g. lateral sides) of the partitioning protrusion member.

According to various other aspects, when the main body 111 of the device 110 defines a plurality of die-receiving-spaces 115, a pair of neighboring (or immediately adjacent) die-receiving-spaces 115 may be adjoined, while differing in size and shape from each other, without any physical partition between them. For instance, one die-receiving-space 115 may be larger (e.g. adapted to accommodate a larger die 170), while an adjacent die-receiving-space 115 may be smaller (e.g. tailored for a different, more compact die 170 or component).

According to various other aspects, these configurations of the device 110 allow for flexible integration of various component(s) within a single assembly 1000 (which incorporates the device 110), enabling efficient use of space while accommodating specific requirements of various dies 170.

According to various aspects, the panel portion 112 and the protrusion arrangement 113 of the main body 111 of the device 110 may be integral (e.g. may be an integral structure) or may be integrally formed. For instance, both the panel portion 112 and the protrusion arrangement 113 may be formed or composed of a same material or material composite. However, it is also envisaged that, in various other aspects, the panel portion 112 and the protrusion arrangement 113 may be discrete portions which may be joined or coupled (e.g. directly or indirectly coupled) to each other via any suitable element (e.g. adhesive, fastener, etc.). It is also envisaged that, in various other aspects, the panel portion 112 and the protrusion arrangement 113 may be formed or composed of different materials or material composites from each other.

According to various aspects, the main body 111 (or both the panel portion 112 and the protrusion arrangement 113) may be formed or composed of a rigid or substantially rigid, strong, tough, and/or hard, etc., material or material composite. Additionally, according to various aspects, the material or material composite of the main body 111 (or of each of the panel portion 112 and the protrusion arrangement 113 thereof) may possess at least one or more of the following properties: heat-resistant, thermally insulating, low thermal expansion or low coefficient of thermal expansion, electrically non-conductive or electrical insulating, and/or high dielectric strength. As some examples, according to various aspects, the main body 111 (or each of the panel portion 112 and the protrusion arrangement 113 thereof) may include or may be composed of an organic mold compound (i.e. a polymer-based material), a polymer or polymer composite, epoxy resin (e.g. including silica filler), polyester resin, polyethylene, polypropylene, thermoplastics, ceramic-based material, or any other suitable material or material composite.

According to various aspects, referring to FIG. 1B, the device 110 may include at least one power management component 121 within the panel portion 112. Specifically, as shown in FIG. 1B, according to various aspects, the at least one power management component 121 may be embedded within the panel portion 112 itself. According to various aspects, the at least one power management component 121 may include or may be at least one voltage regulator, which may be configured to maintain a constant output voltage (e.g. regardless of any fluctuations in input voltage or load conditions). As illustrated in FIG. 1B, the device 110 may include a plurality of voltage regulators (e.g. three voltage regulators). Nevertheless, it is also envisaged that, in various other aspects, the device 110 may include any other number of voltage regulator(s) (as required) (e.g. based on factors, such as a number of corresponding die(s) 170 on the substrate 150, die functionality, and specific voltage requirements).

According to various aspects, the device 110 may include (e.g. further include) an interconnect (e.g. an electrical interconnect) (herein referred to as “device-interconnect 130”, for ease of description). As some examples, according to various aspects, the device-interconnect 130 may include one or a combination (or arrangement) of two or more of electrical or electrically conductive pathway(s), trace(s), via(s), wire(s), pad(s), plane (e.g. metal plane, power plane), conductive/metal redistribution layer, etc., and/or any other suitable medium configured to facilitate the transfer or delivery of power, signals, or data between components.

According to various aspects, the device 110 may include (e.g. further include) at least one reference or ground plane 138 (or Vss) which may serve as a stable voltage reference for electrical signals. According to various aspects, the reference or ground plane 138 may be at least partially embedded within the main body 111 (e.g. at the panel portion 112) of the device 110.

According to various aspects, the device-interconnect 130 may include at least one primary (e.g. a first) connection point (e.g. node, endpoint or trace endpoint, terminal, contact point, etc.) and at least one auxiliary (e.g. second or further) connection point (e.g. node, endpoint or trace endpoint, terminal, contact point, etc.). According to various aspects, the primary connection point and the at least one auxiliary connection point may be located at opposite ends of the device-interconnect 130 (or at opposite ends of a respective conductive trace of the device-interconnect 130). Accordingly, the primary connection point and the at least one auxiliary connection point may be electrically connected or coupled to each other.

According to various aspects, the primary connection point may be electrically coupled to the at least one power management component 121 (and/or at least one passive component 122, described later) at the panel portion 112 of the main body 111 of the device 110. In contrast, the auxiliary connection point 131 (see, for example, FIG. 1C) may be situated away from (or apart or outside) the panel portion 112. In this manner, the auxiliary connection point 131 may serve as an interface for enabling (external) dies 170 to be electrically connected or coupled to the at least one power management component 121 of the device 110. According to various aspects, this enables flexible configurations, easy integration or replacement of the device 110, seamless upgrades, and scalability. Furthermore, this configuration of the device 110 may accommodate various (external) electrical components beyond just dies 170.

FIG. 1C shows a cross-sectional view of the device 110 separated from the substrate 150, according to various aspects.

As shown in FIG. 1C, when the device 110 is separated from the substrate 150, the auxiliary connection point 131 of the device 110 may be exposed, serving as a convenient electrical interface for connecting to (external) components, such as the die 170 on the substrate 150.

In particular, according to various aspects, with reference to FIG. 1C, the auxiliary connection point 131 may be configured to be electrically connectable to an (external) connection point 161 positioned on the surface of the substrate 150. This connection point 161 may, in turn, be electrically connected to a component (e.g. the die 170) disposed on the substrate 150.

As illustrated in FIG. 1C, the auxiliary connection point 131 may be located at an end (or end surface) of the protrusion arrangement 113, which is distal or farthest from the panel portion 112. According to various aspects, said end of the protrusion arrangement 113 may be a flat or substantially flat end surface on which the device 110 may stand on the surface of the substrate 150. Consequently, at least a segment of the device-interconnect 130, immediately adjacent and adjoined to the auxiliary connection point 131, may be embedded within the protrusion arrangement 113 of the main body 111. In various aspects, at least this segment of the device-interconnect 130 may be parallel or substantially parallel to the protrusion arrangement 113 (i.e. along the z-axis). Thus, both this segment of the device-interconnect 130 and the protrusion arrangement 113 may be extending or protruding from the panel portion 112 in a same direction, non-parallel (e.g. perpendicular or substantially perpendicular) to the panel portion 112.

According to various aspects, with reference to FIG. 1C, the device-interconnect 130 may include a plurality of auxiliary connection points 131, functioning as interfaces (e.g. discrete electrical interfaces). According to various aspects, at least a subset or all of the plurality of auxiliary connection points 131 may be electrically connected to a single primary connection point or to multiple primary connection points of the device-interconnect 130 of the device 110. According to various aspects, when the device 110 includes a plurality of auxiliary connection points 131, as well as a plurality of protrusion members 113a, 113b, each auxiliary connection point 131 may be located at the end surface of a respective or corresponding protrusion member 113a, 113b, as shown in FIG. 1C.

In various other aspects, shown for example in FIG. 1D and FIG. 1E, the auxiliary connection point (or at least one auxiliary connection point) may extend into and/or may be situated within a corresponding die-receiving-space 115 of the device 110.

Referring back to FIG. 1B, according to various aspects, the device 110 may include (e.g. further include) at least one passive component 122 disposed at (e.g. within) the panel portion 112 of the main body 111 of the device 110. According to various aspects, this at least one passive component 122 may be electrically connected or coupled (e.g. directly or indirectly) to the at least one power management component 121. As some examples, according to various aspects, the at least one passive component 122 may include or may be at least one amplifier, at least one resistor, at least one transistor, and/or at least one capacitor, etc., and/or any other suitable passive component 122 capable of supporting functionality of the power management component 121 (e.g. a voltage regulator). As an illustration in FIG. 1B, the device 110 may include a plurality of passive components 122 (e.g. three passive components 122). Nevertheless, it is also envisaged that, in various other aspects, the device 110 may include any other number of passive component(s) 122 (as required).

According to various aspects, the at least one power management component 121 and/or the at least one passive component 122 of the device 110 may be aligned within the panel portion 112. For example, they may be situated along a same reference plane (e.g. horizontal reference plane) at the panel portion 112 (e.g. parallel or substantially parallel to the substrate 150).

In various other aspects (not shown), two or more of the at least one power management component 121 and/or the at least one passive component 122 may be situated on different or separate reference planes within the panel portion 112. For example, the two or more power management component(s) 121 and/or the at least one passive component(s) 122 may be in a layered arrangement within the panel portion 112.

According to various aspects, the protrusion arrangement 113 (or each protrusion member 113a, 113b) of the main body 111 of the device 110 may be, but is not limited to being, free of any power management component 121 and/or passive component 122.

FIG. 1D shows a cross-sectional view of the device 110 having a bridge-interconnection-branch 133, according to various aspects.

According to various aspects, the device 110 may include a device-interconnect 130 with at least one auxiliary connection point (herein referred to as “bridge-interconnection-point 132”) configured or adapted to be electrically connectable or couplable (e.g. directly or indirectly) to an interconnect bridge 171 (e.g. an Embedded Multi-die Interconnect bridge or EMIB, a silicon bridge, or glass bridge, etc.) embedded (e.g. partially or completely embedded) within the substrate 150. According to various aspects, this interconnect bridge 171 may be configured to interconnect multiple dies 170 on the substrate 150, for example, linking a die 170b (e.g. a central processing unit or a system-on-chip) and another die 170c (e.g. a graphic processing unit, a neural network processing unit, a tensor processing unit, or a high-bandwidth memory), which may both be mounted on the surface of the substrate 150. According to various aspects, the interconnect bridge 171 may enable power and/or signal transmission between the die 170b and the other die 170c. According to various aspects, the bridge-interconnection-point 132 of the device-interconnect 130 may be electrically connectable or couplable to a corresponding electrical interface (e.g. pad, contact point, etc.) of the interconnect bridge 171. In this setup, according to various aspects, the bridge-interconnection-point 132 may interface and/or be directed towards the electrical interface of the interconnect bridge 171.

As illustrated in FIG. 1D, according to various aspects, the bridge-interconnection-point 132 of the device-interconnect 130 may be positioned between a pair of protrusion members 113a, 113b of the protrusion arrangement 113 of the main body 111 of the device 110. In particular, at least a segment of the device-interconnect 130 or a respective branch of the device-interconnect 130 (henceforth, collectively referred to as “bridge-interconnection-branch 133”), having the bridge-interconnection-point 132, may extend from the panel portion 112 of the main body 111 into the die-receiving-space 115 that is between the pair of protrusion members 113a, 113b. According to various aspects, the bridge-interconnection-branch 133 may extend across the entire height (i.e. along the z-axis) of the die-receiving-space 115. As such, the bridge-interconnection-point 132 of the bridge-interconnection-branch 133 (i.e. located distally or farthest from the panel portion 112) may be substantially aligned with (or may lie on a same horizontal plane) as the distal ends of the pair of protrusion members 113a, 113b. According to various aspects, the bridge-interconnection-point 132 may be electrically connectable or couplable to at least one power (i.e. Vcc) or ground (i.e. Vss) plane in the interconnect bridge 171, for example, via solder bump(s), micro-via(s), etc.

According to various aspects, the bridge-interconnection-branch 133 of the device-interconnect 130 may be a linear structure and may be oriented non-parallel (e.g. perpendicularly or substantially perpendicularly) to the panel portion 112. According to various aspects, the bridge-interconnection-branch 133 of the device-interconnect 130 may also be parallel, or may be non-parallel, with respect to a protrusion member 113a, 113b of the protrusion arrangement 113 of the main body 111 of the device 110.

According to various aspects, the main body 111 of the device 110 may include (e.g. further include) a duct or sleeve (herein referred to as “bridge-interconnection-sleeve 134”) configured to house the bridge-interconnection-branch 133. According to various aspects, this bridge-interconnection-sleeve 134 may define a hollow channel or passageway through and/or along which the bridge-interconnection-branch 133 passes. According to various aspects, the bridge-interconnection-sleeve 134 may serve as a protective housing and guiding structure to the bridge-interconnection-branch 133, facilitating interconnection between the bridge-interconnection-point 132 of the bridge-interconnection-branch 133 and the corresponding electrical interface of the interconnect bridge 171 at the substrate 150. According to various aspects, the bridge-interconnection-sleeve 134 may extend from the panel portion 112, across the entire height (i.e. along the z-axis) of the die-receiving-space 115. According to various aspects, both the bridge-interconnection-sleeve 134 and the bridge-interconnection-branch 133 may run parallel to a protrusion member 113a, 113b of the protrusion arrangement 113. According to various aspects, a length of the bridge-interconnection-sleeve 134 (measured along the z-axis) may be equal or substantially equal to the height of the protrusion member 113a, 113b (i.e. along the z-axis).

According to various aspects, the bridge-interconnection-sleeve 134 may be composed of a same material or material composite as the panel portion 112. Accordingly, in various aspects, the bridge-interconnection-sleeve 134 and the panel portion 112 may be integral or integrally formed. According to various other aspects, the bridge-interconnection-sleeve 134 may be composed of a different material or material composite from the panel portion 112, and may be joined or coupled to the panel portion 112 via any suitable technique or mechanism, such as adhesive bonding or mechanical fasteners. According to various aspects, the bridge-interconnection-sleeve 134 may be composed of a material or material composite possessing at least one or more of the following properties: rigid or substantially rigid, strong, tough, hard, heat-resistant, thermally insulating, low thermal expansion or low coefficient of thermal expansion, electrically non-conductive or electrical insulating, and/or high dielectric strength.

Additionally, according to various aspects, the bridge-interconnection-branch 133 and/or the bridge-interconnection-sleeve 134 may be situated in proximity (e.g. near) to and/or between (e.g. directly between) a power management component 121 (and/or a passive component 122) of the device 110 and the corresponding interconnect bridge 171 at the substrate 150 (i.e. which the device 110 may be assembled with). In other words, according to various aspects, within the device 110, the bridge-interconnection-branch 133 and/or the bridge-interconnection-sleeve 134 may be vertically aligned with a power management component 121 (and/or a passive component 122) of the device 110. Furthermore, according to various aspects, at least a substantial segment of the bridge-interconnection-branch 133 or the entirety of the bridge-interconnection-branch 133 itself and/or the entirety of the bridge-interconnection-sleeve 134 may be linear and perpendicular to the panel portion 112.

According to various aspects, the bridge-interconnection-branch 133 and the bridge-interconnection-sleeve 134 may together serve as an efficient pathway (e.g. a vertical/bypass conduit or “shortcut”, which may be referred to a “direct-bridge-interconnection-bypass”) for power and/or signal transfer.

According to various aspects, the direct-bridge-interconnection-bypass may include a plurality of bridge-interconnection-branches 133 corresponding to (e.g. configured as or resembling) a plurality of extension vias for facilitating power and/or signal delivery between the power management component 121 (and/or passive component 122) of the device 110 and the interconnect bridge 171 at the substrate 150.

According to various aspects, the direct-bridge-interconnection-bypass may be an integrally formed portion of the device 110. For instance, the direct-bridge-interconnection-bypass may be integrally formed with the panel portion 112 of the main body 111 of the device 110.

According to various aspects, a transverse cross-sectional shape or profile of the bridge-interconnection-sleeve 134 may differ from, or may be identical to, that of a protrusion member 113a, 113b of the protrusion arrangement 113 of the main body 111. As an example, according to various aspects, the bridge-interconnection-sleeve 134 may be cylindrical and may define the passageway for the bridge-interconnection-branch 133 along a longitudinal axis (or central axis) of the cylindrical bridge-interconnection-sleeve 134.

FIG. 1E shows a cross-sectional view of the device 110 having a die-interconnection-branch 136, according to various aspects.

According to various aspects, the device 110 may include a device-interconnect 130 with at least one auxiliary connection point (herein referred to as “die-interconnection-point 135”) configured or adapted to be electrically connectable or couplable (e.g. directly or indirectly) to at least one die 170 on the substrate 150. According to various aspects, the at least one die 170 may be disposed either directly or indirectly over and/or on the surface of the substrate 150. As an example, shown in FIG. 1E, according to various aspects, the aforesaid at least one die 170 may be a base die 170d that may be mounted directly on the surface of the substrate 150, and the die-interconnection-point 135 may be configured to be electrically connectable (e.g. directly) to this base die 170d. As another example (see, for example, FIG. 1F), according to various other aspects, the aforesaid at least one die 170 may include or may be at least one chiplet 170e (e.g. silicon chiplet) which may be mounted on the base die 170d, with the base die 170d mounted directly on the surface of the substrate 150, and the die-interconnection-point 135 may be configured to be electrically connectable (e.g. directly) to the at least one chiplet 170e. Thus, the base die 170d may be between the at least one chiplet 170e and the substrate 150. According to various aspects, with reference to FIG. 1E, the die-interconnection-point 135 of the device-interconnect 130 may be couplable or connectable to a corresponding electrical interface (e.g. pad, ball, contact point, etc.) of the at least one die 170 (e.g. base die 170d) at the substrate 150. In this setup, according to various aspects, the die-interconnection-point 135 may interface and/or be directed towards the electrical interface of the at least one die 170 (e.g. base die 170d).

As illustrated in FIG. 1E, according to various aspects, the die-interconnection-point 135 of the device-interconnect 130 may be positioned between a pair of protrusion members 113a, 113b of the protrusion arrangement 113 of the main body 111. In particular, at least a segment of the device-interconnect 130 or a respective branch of the device-interconnect 130 (henceforth, collectively referred to as “die-interconnection-branch 136”), having the die-interconnection-point 135, may extend from the panel portion 112 of the main body 111 into the die-receiving-space 115 that is situated between the pair of protrusion members 113a, 113b. According to various aspects, the die-interconnection-branch 136 may be shorter (i.e. along the z-axis) than the bridge-interconnection-branch 133 of FIG. 1D. Accordingly, according to various aspects, the die-interconnection-branch 136 may be shorter than a height (i.e. along the z-axis) of the die-receiving-space 115.

According to various aspects, the die-interconnection-branch 136 of the device-interconnect 130 may be a linear structure and may be oriented non-parallel (e.g. perpendicularly or substantially perpendicularly) to the panel portion 112. According to various aspects, the die-interconnection-branch 136 of the device-interconnect 130 may also be parallel, or may be non-parallel, with respect to a protrusion member 113a, 113b of the protrusion arrangement 113 of the main body 111 of the device 110.

According to various aspects, the main body 111 of the device 110 may include (e.g. further include) a duct or sleeve (herein referred to as “die-interconnection-sleeve 137”) configured to house the die-interconnection-branch 136. According to various aspects, this die-interconnection-sleeve 137 of FIG. 1E may be shorter (e.g. in length and/or along the z-axis) than the bridge-interconnection-sleeve 134 of FIG. 1D, but may include one or more other feature(s) corresponding (e.g. similar or identical) to that of the bridge-interconnection-sleeve 134 of FIG. 1D.

According to various aspects, the die-interconnection-sleeve 137 may define a hollow channel or passageway through and/or along which the die-interconnection-branch 136 passes.

According to various aspects, the die-interconnection-sleeve 137 may serve as a protective housing and guiding structure to the die-interconnection-branch 136 of the device-interconnect 130, facilitating interconnection between the die-interconnection-point 135 of the die-interconnection-branch 136 and a corresponding electrical interface of the at least one die 170 (e.g. base die 170d) that is positioned at the substrate.

According to various aspects, the die-interconnection-sleeve 137 may be composed of a same material or material composite as the panel portion 112 of the main body 111 of the device 110, or the die-interconnection-sleeve 137 may be composed of a different material or material composite from the panel portion 112. According to various aspects, the die-interconnection-sleeve 137 may be composed of a material or material composite possessing at least one or more of the following properties: rigid or substantially rigid, strong, tough, hard, heat-resistant, thermally insulating, low thermal expansion or low coefficient of thermal expansion, electrically non-conductive or electrical insulating, and/or high dielectric strength.

Additionally, according to various aspects, the die-interconnection-branch 136 and/or the die-interconnection-sleeve 137 may be situated in proximity to and/or between (e.g. directly between) a power management component 121 (and/or a passive component 122) of the device 110 and at least one die 170 at the substrate 150 (i.e. which the device 110 may be assembled with). In other words, according to various aspects, with the device 110, the die-interconnection-branch 136 and/or the die-interconnection-sleeve 137 may be vertically aligned with a power management component 121 (and/or a passive component 122) of the device 110. Furthermore, according to various aspects, at least a substantial segment of the die-interconnection-branch 136 or the entirety of the die-interconnection-branch 136 itself and/or the entirety of the die-interconnection-sleeve 137 may be linear and perpendicular to the panel portion 112.

According to various aspects, the die-interconnection-branch 136 and the die-interconnection-sleeve 137 may together serve as an efficient pathway (e.g. a vertical/bypass conduit or “shortcut”, which may be referred to a “direct-die-interconnection-bypass”) for power and/or signal transfer.

According to various aspects, the direct-die-interconnection-bypass may include a plurality of die-interconnection-branches 136 corresponding to (e.g. configured as or resembling) a plurality of extension vias for facilitating power and/or signal delivery between the power management component 121 (and/or passive component 122) of the device 110 and the at least one die 170 at the substrate 150.

According to various aspects, the direct-die-interconnection-bypass may be an integrally formed portion of the device 110. For instance, the direct-die-interconnection-bypass may be integrally formed with the panel portion 112 of the main body 111 of the device 110.

According to various aspects, a transverse cross-sectional shape or profile of the die-interconnection-sleeve 137 may differ from, or may be identical to, that of a protrusion member 113a, 113b of the protrusion arrangement 113 of the main body 111. As an example, according to various aspects, the die-interconnection-sleeve 137 may be cylindrical and may define the passageway for the die-interconnection-branch 136 along a longitudinal axis (or central axis) of the cylindrical die-interconnection-sleeve 137.

FIG. 1F shows a cross-sectional view of the device 110 having both the bridge-interconnection-branch 133 and the die-interconnection-branch 136, according to various aspects.

According to various aspects, with reference to FIG. 1F, the device-interconnect 130 of the device 110 may include at least one (i.e. one or more) bridge-interconnection-branch 133 having at least one corresponding bridge-interconnection-point 132 and at least one die-interconnection-branch 136 having at least one corresponding die-interconnection-point 135.

According to various aspects, both the at least one bridge-interconnection-branch 133 and the at least one die-interconnection-branch 136 may extend into and/or be situated within one or more corresponding die-receiving-space(s) 115 of the main body 111 of the device 110.

In various other aspects, when the main body 111 of the device 110 includes a plurality of die-receiving-spaces 115 (not shown in FIG. 1F), the device 110 may be configured such that the at least one bridge-interconnection-branch 133 may extend into and/or be situated within a first die-receiving-space 115, while the at least one die-interconnection-branch 136 may extend into and/or be situated within a second (i.e. another) die-receiving-space 115.

It is also envisaged that, according to various aspects, the at least one bridge-interconnection-branch 133 and the at least one die-interconnection-branch 136 may be positioned at any (e.g. other) suitable location within the device 110.

FIG. 2A shows a perspective view of a schematic diagram of the device 110 having at least one ventilation opening 116 for a heat-dissipation arrangement 180, according to various aspects.

FIG. 2B shows a cross-sectional view taken along line B-B of FIG. 2A, according to various aspects.

According to various aspects, with reference to FIG. 2A, the main body 111 of the device 110 may include or define at least one through-hole 116 extending across the main body 111, between an inner surface and an opposite outer surface of the main body 111.

As illustrated in FIG. 2A and FIG. 2B, according to various aspects, the at least one through-hole 116 may be extending across the panel portion 112. Specifically, the at least one through-hole 116 may be extending between the inner surface (e.g. bottom surface) and an opposite outer surface (e.g. upper surface) of the panel portion 112. However, it is also envisaged that, in various other aspects (not shown), the at least one through-hole 116 may be positioned at the protrusion arrangement 113 of the main body 111, or the main body 111 may have through-holes 116 at both the panel portion 112 and the protrusion arrangement 113.

According to various aspects, each through-hole 116 of the main body 111 may open to a corresponding die-receiving-space 115 and may serve as a ventilation opening (e.g. port or vent), allowing thermal exchange between the inside of the main body 111 (i.e. the die-receiving-space 115) and the outside of the main body 111 of the device 110. Accordingly, the ventilation opening (i.e. through-hole 116) may enable or enhance thermal exchange, such as cool air from outside the device 110 entering into the die-receiving-space 115, or hot air from inside the die-receiving-space 115 exiting through the ventilation opening. For ease of description, each such through-hole 116 of the main body 111 of the device 110 may henceforth be referred to as a “ventilation opening 116”.

According to various aspects, the ventilation opening 116 may be associated or paired with a corresponding heat-dissipation arrangement 180 (e.g. one or more of a thermally conductive/metal plug, thermal head, pedestal, heat sink, heat pipe, and/or fluid or liquid channel, etc.) which may be thermally coupled (e.g. directly or indirectly) to the at least one die 170 at the substrate 150 to facilitate or enhance heat or thermal dissipation from the at least one die 170. For instance, the heat-dissipation arrangement may include a heat pipe or a fluid (e.g. liquid or air) channel (or duct) which may be coupled to a thermal head or thermally conductive pedestal which, in turn, may be coupled to the at least one die 170.

According to various aspects, the ventilation opening 116 may be arranged or positioned such that, when the device 110 is assembled on the substrate 150, heat may efficiently dissipate from the heat-dissipation arrangement 180 through the ventilation opening 116 of the main body 111 of the device 110. To illustrate, with reference to FIG. 2A and FIG. 2B, the ventilation opening 116 may be aligned with the heat-dissipation arrangement 180, when the device 110 is attached to the substrate 150. In particular, the ventilation opening 116 may be aligned with and/or over (e.g. directly or at least partially over) at least a portion of the heat-dissipation arrangement 180, when the device 110 is attached to the substrate 150. Specifically, a hole axis (not shown) of the ventilation opening 116 may intersect at least a portion of the heat-dissipation arrangement 180. According to various aspects, the ventilation opening 116 (i.e. through-hole) may extend linearly along its hole axis, which may be non-parallel (e.g. perpendicular or substantially perpendicular) to the panel portion 112 and/or to the surface of the substrate 150.

Additionally, according to various aspects, the ventilation opening 116 may be configured (e.g. dimensioned, shaped and/or sized) to receive the heat-dissipation arrangement 180 (e.g. a thermally-conductive/metal plug) when the device 110 is attached to the substrate 150. Hence, a size (or transverse cross-sectional area) of the ventilation opening 116 may be larger than that of the heat-dissipation arrangement 180 (or its upper segment), allowing the heat-dissipation arrangement 180 (e.g. at least its upper segment) to be received within the ventilation opening 116 of the main body 111 of the device 110, as shown in FIG. 2A. According to various aspects, when the heat-dissipation arrangement 180 (or a segment thereof) is within the ventilation opening 116, the heat-dissipation arrangement 180 (or at least the aforesaid segment) may be separated, isolated (e.g. electrically isolated), and/or insulated (e.g. electrically insulated) from the device-interconnect 130 of the device 110. In particular, the main body 111 may serve to insulate the device-interconnect 130 from the heat-dissipation arrangement 180. Moreover, according to various aspects, the heat-dissipation arrangement 180 may be spaced apart (e.g. by a void or gap) from the surrounding surfaces of the main body 111 which define the ventilation opening 116.

According to various aspects, when the main body 111 of the device 110 includes the ventilation opening 116, the device-interconnect 130 of the device 110 may include at least one conductive path running lengthwise of the panel portion 112 (i.e. along the y-axis), around and/or alongside the ventilation opening 116.

FIG. 2C shows a cross-sectional view of the device 110 having a plurality of die-receiving-spaces 115a, 115b, 115c and a plurality of ventilation openings 116a, 116b, 116c, according to various aspects

With reference to FIG. 2C, according to various aspects, the main body 111 of the device 110 may include a plurality of die-receiving-spaces 115a, 115b, 115c. In particular, the main body 111 may include at least a first die-receiving-space 115a for accommodating or housing a first die 170a (e.g. a central processing unit, a system-on-chip, etc.) and a second die-receiving-space 115b (e.g. distinct and/or separate from the first die-receiving-space 115a) for accommodating a second die 170b (e.g. a graphic processing unit, a neural network processing unit, a tensor processing unit, etc.). Additionally, the main body 111 may include a third or further die-receiving-space 115c (e.g. distinct and/or separate from each of the first and the second die-receiving-spaces 115a, 115b) for accommodating a third die 170c (e.g. a high bandwidth memory, a DRAM memory device, etc.).

As further illustrated in FIG. 2C, the main body 111 of the device 110 may include a plurality of ventilation openings 116a, 116b, 116c that enable thermal exchange and/or fluid connection between the plurality of die-receiving-spaces 115a, 115b, 115c and an external environment. In particular, the main body 111 may include at least one ventilation opening 116a (herein referred to as “first ventilation opening 116a”) connected to (or that opens to, e.g. to only) the first die-receiving-space 115a and at least one other ventilation opening 116b (herein referred to as “second ventilation opening 116b”) connected to (e.g. to only) the second die-receiving-space 115b. Additionally, the main body 111 may include at least one other ventilation opening 116c (herein referred to as “third ventilation opening 116c”) connected to (e.g. to only) the third die-receiving-space 115c.

Moreover, according to various aspects, each of the first ventilation opening 116a, the second ventilation opening 116b, and/or the third ventilation opening 116c may be adapted (e.g. dimensioned, shaped and/or sized) to accommodate or receive at least a segment (e.g. an upper segment) of the heat-dissipation arrangement 180. For example, with reference to FIG. 2C, a first heat-dissipation member 180a (e.g. a thermal head or pedestal) of the heat-dissipation arrangement 180 may be thermally coupled to the first die 170a within the first die-receiving-space 115a, with an upper or topmost segment of the first heat-dissipation member 180a extending into and/or through the first ventilation opening 116a. Similarly, a second heat-dissipation member 180b of the heat-dissipation arrangement 180 may be thermally coupled to the second die 170b within the second die-receiving-space 115b, with its upper or topmost segment extending into and/or through the second ventilation opening 116b. A third heat-dissipation member 180c of the heat-dissipation arrangement 180 may be thermally coupled to the third die 170c within the third die-receiving-space 115c, with its upper or topmost segment extending into and/or through the third ventilation opening 116c. According to various aspects, as illustrated in FIG. 2C, the heat-dissipation members 180a, 180b, 180c may be spaced apart and/or isolated (e.g. thermally isolated) from one another.

With reference to FIG. 1A, according to various aspects, the device 110 and the substrate 150 (e.g. a package substrate) may together form or be part of an assembly 1000 (e.g. a semiconductor assembly or package) or a system.

Accordingly, within the assembly 1000 (or system), the device 110 may be disposed over and/or on (e.g. directly or indirectly on) the substrate 150. In particular, the protrusion arrangement 113 of the device 110 may be placed on the surface of the substrate 150 such that it spaces the panel portion 112 of the device 110 away or apart from (or over) the surface of the substrate 150. As a result, the panel portion 112 of the device 110 may lie on a plane (herein referred to as “panel-portion-positioning-plane”) which may be over (e.g. above) and spaced apart from another plane (herein referred to as “substrate-positioning-plane”) on which the substrate 150 may be disposed. According to various aspects, the panel-portion-positioning-plane and the substrate-positioning-plane may be parallel or substantially parallel to one another.

According to various aspects of the assembly 1000, at least one primary connection point of the device-interconnect 130 of the device 110 may be electrically coupled to at least one power management component 121 and/or passive component 122 at the panel portion 112 of the device 110, while at least one auxiliary connection point 131 (see, for example, FIG. 1C) of the device-interconnect 130 of the device 110 may be positioned away and/or apart from and/or outside the panel portion 112. In particular, within the assembly 1000, the at least one auxiliary connection point 131 of the device-interconnect 130 of the device 110 may be located distally from the panel portion 112 and proximally to the substrate 150.

According to various aspects, the assembly 1000 may include (e.g. further include) at least one die 170 disposed on (e.g. coupled or mounted on) the surface of the substrate 150. Further, within an assembled assembly 1000, the at least one die 170 may be disposed (or housed or accommodated) within a corresponding die-receiving-space 115 of the device 110. Thus, according to various aspects, the at least one die 170 may be situated between the substrate 150 and the panel portion 112 of the main body 111 of the device 110 (or between the panel-portion-positioning-plane and the substrate-positioning-plane). According to various aspects, the at least one power management component 121 and/or the at least one passive component 122 at the panel portion 112 of the device 110 may be situated at the panel portion 112, on a different reference plane from the at least one die 170 at the substrate 150. In particular, the at least one power management component 121 and/or the at least one passive component 122 of the device 110 may be situated above (e.g. partially or directly above, or above but offset from) the at least one die 170 at the substrate 150.

As some examples, according to various aspects, the at least one die 170 may include one or more of a central processing unit, a system-on-chip, a graphic processing unit, a neural network processing unit, a tensor processing unit, and/or a high-bandwidth memory (e.g. DRAM memory), etc.

According to various aspects of the assembly 1000, the at least one auxiliary connection point 131 of the device-interconnect 130 of the device 110 may be electrically coupled to the at least one die 170, for example, via at least one corresponding connection point 161 (see FIG. 1C) on the substrate 150, which may include solder bump(s) or any other suitable conductive element. The at least one connection point 161 may, in turn, be electrically connected to the at least one die 170 via an interconnect 160 of the substrate 150 (herein referred to as “substrate-interconnect 160”), which may include one or a combination (or arrangement) of two or more of electrical or electrically conductive pathway(s), trace(s), via(s), wire(s), pad(s), plane (e.g. package plane or power plane), conductive/metal redistribution layer, etc., and/or any other suitable medium configured to facilitate the transfer or delivery of power, signals, or data. As an illustration, according to various aspects, the substrate-interconnect 160 (e.g. its package plane, power plane, etc.) may be configured to facilitate (or support) a power supply between 0.4V and 5V. For example, a package plane or power plane of the substrate-interconnect 160 may be configured to facilitate a 3.3V power supply. As another example, the power plane of the substrate-interconnect 160 may be configured to facilitate a 0.4V power supply.

With reference to FIG. 1D, according to various aspects of the assembly 1000, the substrate-interconnect 160 may include (e.g. further and/or optionally include) an interconnect bridge 171 which may be embedded (e.g. partially or completely embedded) within the substrate 150. According to various aspects, the assembly 1000 may include at least a pair of dies 170b, 170c on the substrate 150, which may be interconnected or linked via the interconnect bridge 171. According to various aspects, the interconnect bridge 171 may be aligned with (e.g. along the z-axis, and/or may be below or directly below) the panel portion 112 of the device 110.

According to various aspects of the assembly 1000, the device-interconnect 130 of the device 110 may include (e.g. further and/or optionally include) the bridge-interconnection-branch 133 which may extend from the panel portion 112 of the device 110 into the die-receiving-space 115. According to various aspects, the bridge-interconnection-branch 133 (e.g. at least a substantial segment thereof and/or a segment distal from the panel portion 112) may be aligned with (e.g. may be over or directly above) the interconnect bridge 171. According to various aspects, a bridge-interconnection-point 132 at a longitudinal free end of the bridge-interconnection-branch 133 may be electrically connected or coupled to the interconnect bridge 171.

According to various aspects, the assembly 1000 may include the direct-bridge-interconnection-bypass having the bridge-interconnection-branch 133 and the bridge-interconnection-point 132.

With reference to FIG. 1E, according to various aspects of the assembly 1000, the device-interconnect 130 of the device 110 may include (e.g. further and/or optionally include) the die-interconnection-branch 136 which may extend from the panel portion 112 of the device 110 into the die-receiving-space 115 to electrically couple or connect to one or more dies 170 (e.g. base die 170d) on the substrate 150 of the assembly 1000. According to various aspects, the die-interconnection-branch 136 (e.g. at least a substantial segment thereof and/or a segment distal from the panel portion 112) may be aligned with (e.g. may be over or directly above) the one or more dies 170 (e.g. base die 170d). According to various aspects, a die-interconnection-point 135 at a longitudinal free end of the die-interconnection-branch 136 may be electrically connected or coupled to the one or more dies 170.

According to various aspects, the assembly 1000 may include the direct-die-interconnection-bypass having the die-interconnection-branch 136 and the die-interconnection-point 135.

As an illustration, with reference to FIG. 1E, the assembly 1000 may include a base die 170d on the substrate 150, along with one or more chiplets 170e (i.e. one or more dies 170) seated or mounted on the base die 170d. The die-interconnection-branch 136 of the device 110 may extend from the panel portion 112 into the die-receiving-space 115 to establish an electrical connection with the one or more chiplets 170e (i.e. the one or more dies 170). For instance, the die-interconnection-point 135 of the die-interconnection-branch 136 may be electrically connected to the one or more chiplets 170e, for example, through a metal trace or plane located on the base die 170d and/or to a metal redistribution layer that may be integrated or associated with the base die 170d.

With reference to FIG. 2A, according to various aspects of the assembly 1000, the main body 111 of the device 110 may include at least one ventilation opening 116.

As an example, shown in FIG. 2A, the main body 111 may define a die-receiving-space 115 and may further include at least one ventilation opening 116 that is connected or that opens to the die-receiving-space 115. As shown in FIG. 2A, the assembly 1000 may further include a heat-dissipation arrangement 180 thermally coupled to at least one die 170, in the die-receiving-space 115.

In other aspects of the assembly 1000, the main body 111 of the device 110 may define a plurality of die-receiving-spaces 115, with the assembly 1000 including at least one die 170 in each of these die-receiving-spaces 115. In such a configuration, the main body 111 may define a plurality of ventilation openings 116, each connected or opening to a corresponding die-receiving-space 115.

In other aspects, the main body 111 of the device 110 may include at least one ventilation opening 116 for each of any one or more die-receiving-spaces 115 within the device 110.

According to various aspects, with reference to FIG. 2C, when the assembly 1000 includes a plurality of dies 170a, 170b, 170c, the heat-dissipation arrangement 180 may include individual and/or discrete heat-dissipation members 180a, 180b, 180c respectively coupled to the plurality of dies 170a, 170b, 170c. As some examples, according to various aspects, each heat-dissipation member 180a, 180b, 180c may include or may be a thermally conductive (e.g. metal) plug or layer (e.g. which may include or may be composed of copper, aluminum, and/or a metal composite), a heat sink, etc., or any other suitable heat-dissipation member 180a, 180b, 180c. According to various aspects, each heat-dissipation member 180a, 180b, 180c may be positioned or seated on (e.g. above) a corresponding die 170a, 170b, 170c within the assembly 1000. Thus, according to various aspects, when the main body 111 defines a plurality of die-receiving-spaces 115a, 115b, 115c, each die-receiving-space 115a, 115b, 115c may also accommodate or house at least a segment of a corresponding heat-dissipation member 180a, 180b, 180c.

Additionally, according to various aspects of the assembly 1000, each ventilation opening 116 may be associated with a corresponding heat-dissipation member 180a, 180b, 180c. In particular, each ventilation opening 116 may be connected (e.g. directly or indirectly) to the corresponding heat-dissipation member 180a, 180b, 180c. In other words, each ventilation opening 116 may be in fluid communication with the corresponding heat-dissipation member 180a, 180b, 180c. Specifically, according to various aspects, each ventilation opening 116 may be positioned proximal to and/or aligned with (e.g. along the z-axis) a corresponding heat-dissipation member 180a, 180b, 180c. For instance, a hole axis of each ventilation opening 116 may intersect a corresponding heat-dissipation member 180a, 180b, 180c and/or may be aligned (e.g. coincident) with a longitudinal axis (e.g. parallel to the z-axis) of the heat-dissipation member 180a, 180b, 180c.

According to various aspects of the assembly 1000, at least a segment (e.g. an upper or topmost segment) of the heat-dissipation member 180a, 180b, 180c (i.e. situated distally from the substrate 150) may extend into a corresponding ventilation opening 116, as shown in FIG. 2A. Nevertheless, it is also envisaged that, in various other aspects, an entire heat-dissipation member 180a, 180b, 180c may remain within a corresponding die-receiving-space 115 (i.e. without extending into the ventilation opening 116).

According to various aspects, the protrusion arrangement 113 of the main body 111 of the device 110—in particular, a plurality of protrusion members 113a, 113b of the protrusion arrangement 113 which may be spaced apart from one another—may also define opening(s) 117, as shown in FIG. 1A, between the plurality of protrusion members 113a, 113b, which may enable ventilation or heat dissipation (e.g. from the at least one die 170 within the die-receiving-space 115). However, it is also envisaged that, in various other aspects, the protrusion arrangement 113 may fully surround or enclose the die-receiving-space 115, while the panel portion 112 may include at least one ventilation opening 116 (see FIG. 2A) for ventilation or dissipating heat generated by the at least one die 170 in the die-receiving-space 115.

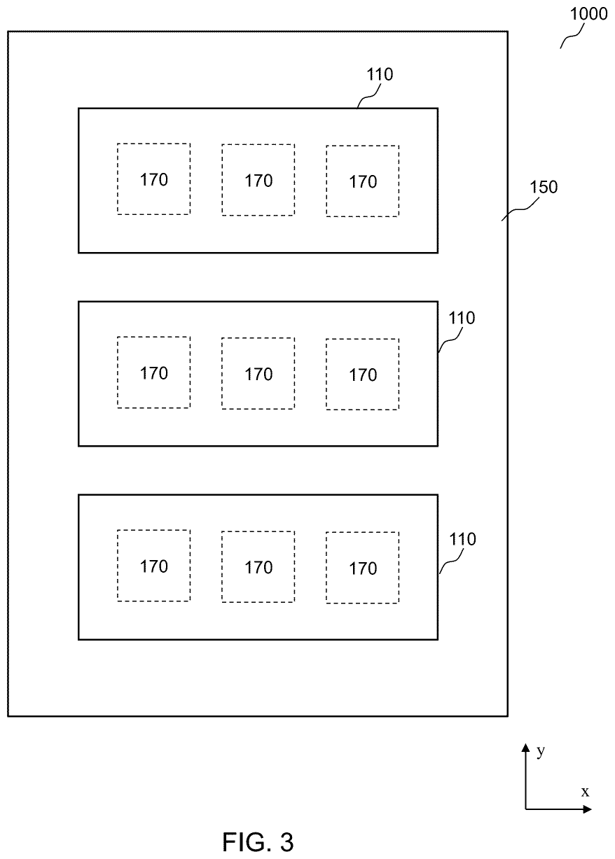

FIG. 3 shows a top view of a schematic diagram of a plurality of devices 110 on the substrate 150, according to various aspects.

According to various aspects, with reference to FIG. 3, the assembly 1000 may include a plurality of devices 110 (e.g. individual and/or discrete devices 110) arranged or assembled on the substrate 150 (e.g. a single, continuous substrate structure).

According to various aspects, at least two of the devices 110 may be similar or identical to each other. For example, at least two of the devices 110 have a similar or identical footprint on the substrate 150, as illustrated in FIG. 3.

According to various aspects, at least two of the devices 110 may define similar or identically sized die-receiving-spaces 115 for accommodating or housing similar or identical arrangements (e.g. layout and/or number) of die(s) 170 and/or heat-dissipation member(s) 180a, 180b, 180c.

According to various aspects, at least two of the devices 110 may have an equivalent number of power management component(s) 121 and/or passive component(s) 122 as each other.

Referring to FIG. 3, according to various aspects of the assembly 1000, all dies 170 mounted on the substrate 150 of the assembly 1000 may be housed within a corresponding die-receiving-space 115 of a corresponding device 110 of the assembly 1000.

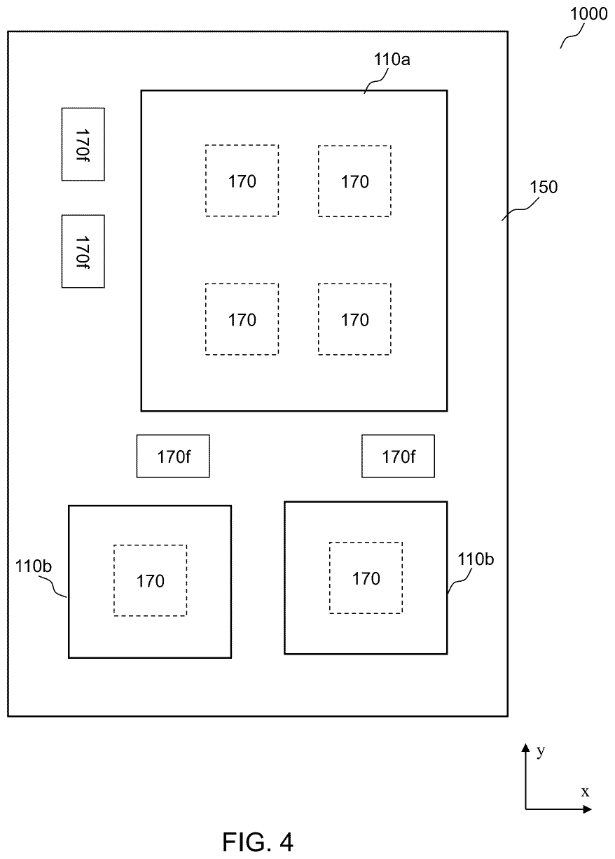

FIG. 4 shows a top view of a schematic diagram of a plurality of differently sized devices 110a, 110b on the substrate 150, according to various aspects.

According to various aspects, with reference to FIG. 4, the assembly 1000 may include a plurality of devices 110a, 110b disposed on the substrate 150 (e.g. a single, continuous substrate structure).

As shown, the plurality of devices 110a, 110b may be, but are not limited to being, spaced apart from one another along the surface of the substrate 150.

According to various aspects, at least two of the plurality of devices 110a, 110b (e.g. individual and/or discrete devices) may be electrically connected to each other (e.g. via the substrate-interconnect 160 of the substrate 150). However, it is also envisaged that at least one of the plurality of devices 110a, 110b may function independently and/or be electrically isolated from other remaining devices 110a, 110b in the assembly 1000.

According to various aspects, at least two of the devices 110a, 110b may differ from each other. For example, at least two of the devices 110a, 110b have different footprints on the substrate 150, as shown in FIG. 4.

According to various aspects, at least two of the devices 110a, 110b may define differently sized die-receiving-spaces 115 for accommodating different arrangements (e.g. layout and/or number) of die(s) 170 and/or heat-dissipation member(s) 180a, 180b, 180c.

According to various aspects, at least two of the devices 110a, 110b may have a different number of power management component(s) 121 and/or passive component(s) 122 from each other.

Referring to FIG. 4, according to various aspects, the assembly 1000 may include at least one die 170f on the substrate 150, located outside of the main bodies (or the die-receiving-spaces 115) of the devices 110a, 110b. In other words, the assembly 1000 may include at least one die 170f that is not within a die-receiving-space 115 of any device 110a, 110b. According to various aspects, this at least one die 170f, which may be located externally of the devices 110a, 110b, may be electrically connected or coupled to at least one other die 170 located within a corresponding die-receiving-space 115 of a device 110a, 110b and/or electrically connected or coupled to the at least one power management component 121 and/or the passive component 122 of that device 110a, 110b (e.g. via the substrate-interconnect 160 and/or the device-interconnect 130 of the device 110a, 110b).

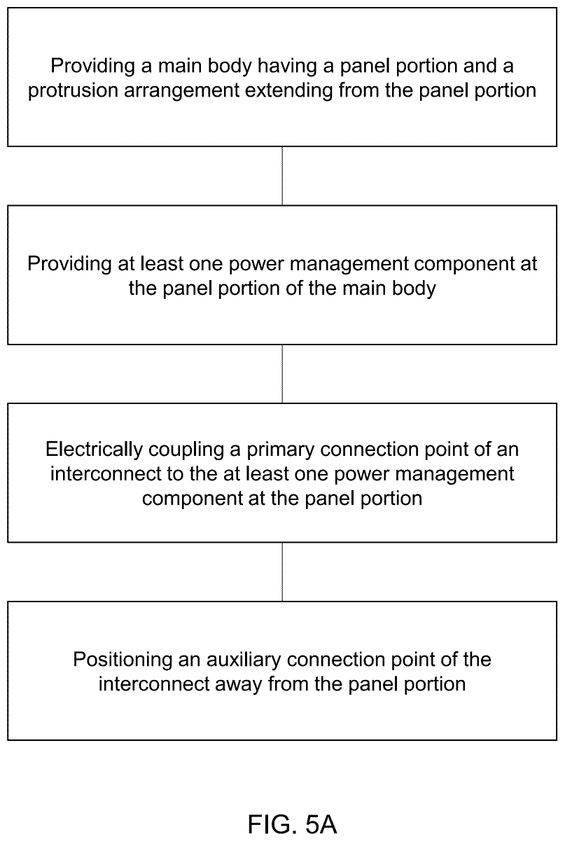

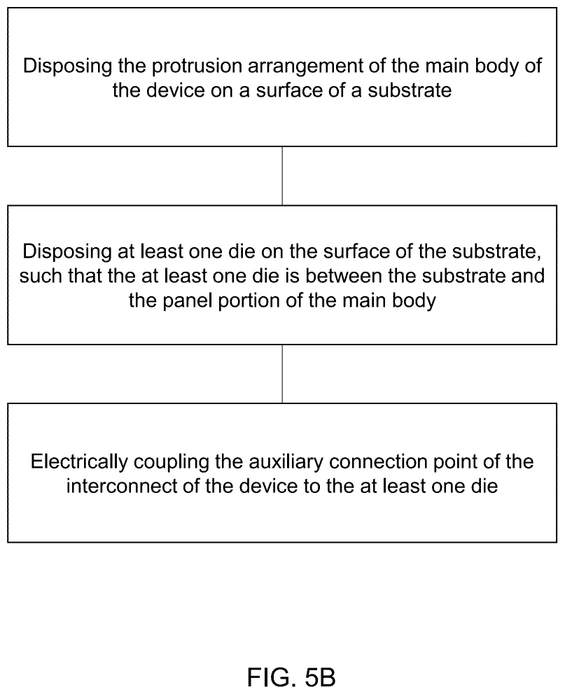

FIG. 5A is a flowchart depicting a process of making the device 110, according to various aspects.

According to various aspects, the process (or method) may include providing the main body 111 having the panel portion 112 and the protrusion arrangement 113 extending from the panel portion 112, the protrusion arrangement 113 being non-parallel to the panel portion 112.

According to various aspects, the process (or method) may include (e.g. further include) disposing or providing at least one power management component 121 at the panel portion 112 of the main body 111.

According to various aspects, the process (or method) may include (e.g. further include) disposing or providing at least one passive component 122 at the panel portion 112 of the main body 111 and electrically coupling the at least one passive component 122 to the at least one power management component 121.

According to various aspects, the process (or method) may include (e.g. further include) providing the device-interconnect 130 having the primary connection point and the auxiliary connection point 131. The primary connection point and the auxiliary connection point 131 may be part (e.g. ends) of an electrical trace of the device-interconnect 130 and may, hence, be electrically connected to each other.

According to various aspects, the process (or method) may include (e.g. further include) electrically coupling the primary connection point of the device-interconnect 130 to the at least one power management component 121 and/or to the at least one passive component 122 at the panel portion 112.

According to various aspects, the process (or method) may include (e.g. further include) positioning the auxiliary connection point 131 away or apart from and/or outside of the panel portion 112.

According to various aspects, the process (or method) may include (e.g. further include) embedding at least a segment of the device-interconnect 130 within the protrusion arrangement 113 of the main body 111.

According to various aspects, the process (or method) may include (e.g. further include) configuring (e.g. arranging, and/or positioning) an (or the) auxiliary connection point 131 of the device-interconnect 130 to extend into the die-receiving-space 115 of the device 110. In other words, the process (or method) may include positioning an (or the) auxiliary connection point 131 of the device-interconnect 130 within the die-receiving-space 115 of the device 110.

FIG. 5B is a flowchart depicting a process of making the assembly 1000, according to various aspects.

According to various aspects, the device 110 may be disposed or placed or stacked on the substrate 150 to form the assembly 1000. For example, the process (or method) may include disposing or placing the protrusion arrangement 113 of the main body 111 on (e.g. directly onto) the surface of the substrate 150, with the panel portion 112 of the main body 111 of the device 110 spaced apart from the surface of the substrate 150 via the protrusion arrangement 113. According to various aspects, the panel portion 112 of the main body 111 of the device 110 may be spaced apart from the surface of the substrate 150 to define the die-receiving-space 115 between the substrate 150 and the panel portion 112.

According to various aspects, the process (or method) may include (e.g. further include) disposing at least one die 170 on the surface of the substrate 150, with the at least one die 170 between the substrate 150 and the panel portion 112 of the main body 111. In other words, the at least one die 170 may be within the die-receiving-space 115. According to various aspects, the at least one die 170 may be disposed on the surface of the substrate 150 before the device 110 is disposed or placed or stacked on the substrate 150.

According to various aspects, the process (or method) may include (e.g. further include) electrically coupling the auxiliary connection point 131 of the device-interconnect 130 of the device 110 to the at least one die 170.

According to various aspects, the process (or method) may include (e.g. further include) coupling (e.g. thermally coupling) the heat-dissipation arrangement 180 to the at least one die 170. According to various aspects, the heat-dissipation arrangement 180 may be coupled to the at least one die 170 before the device 110 is disposed or placed or stacked on the substrate 150.

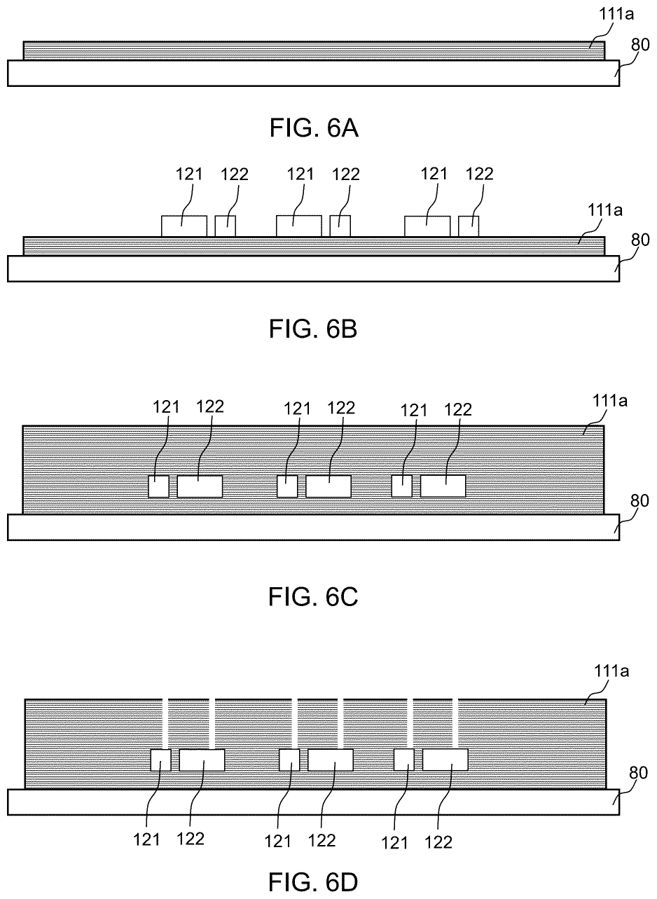

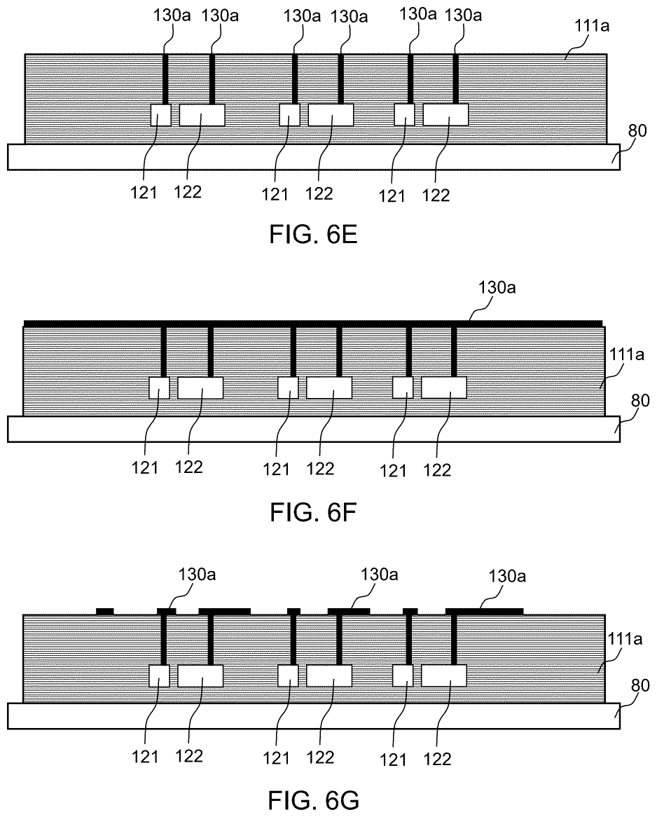

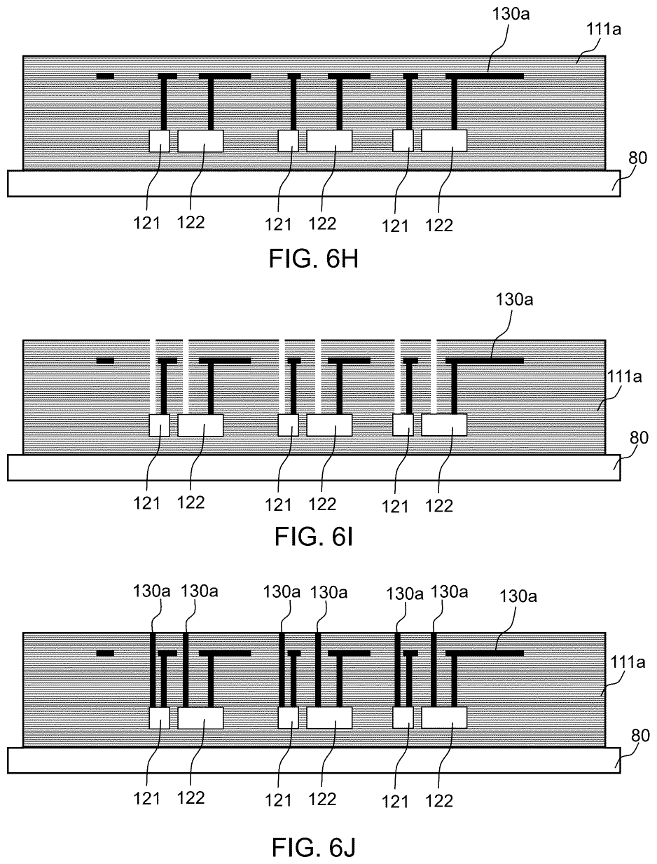

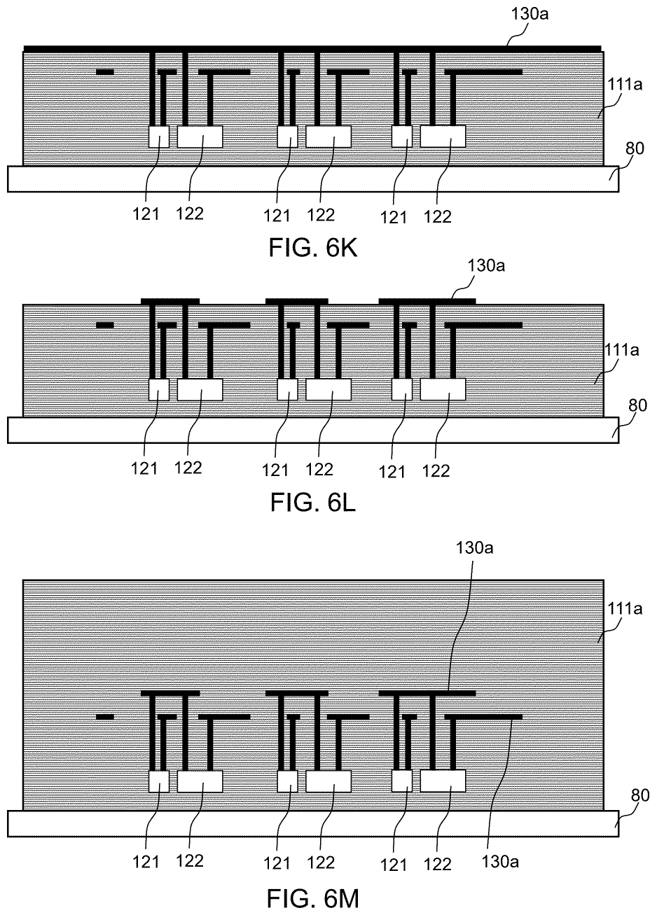

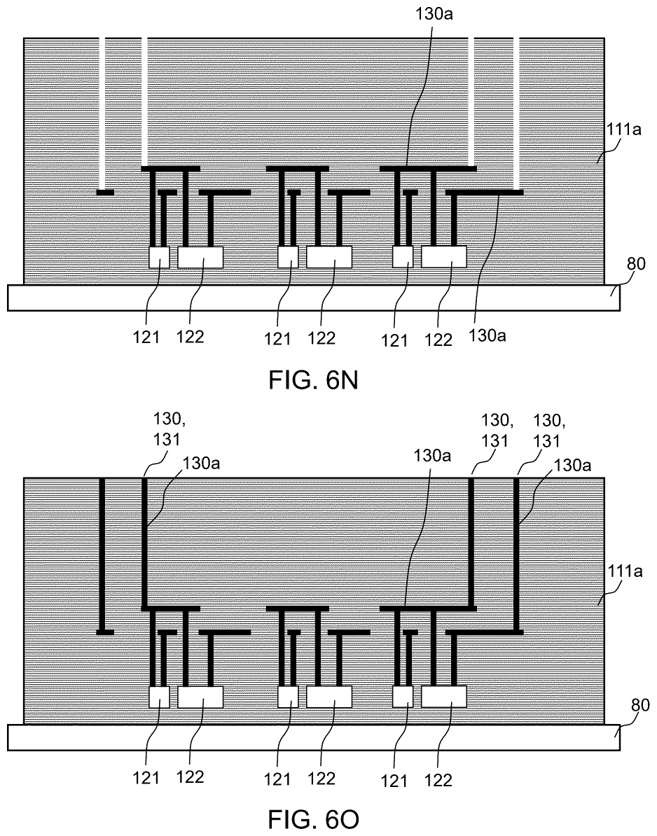

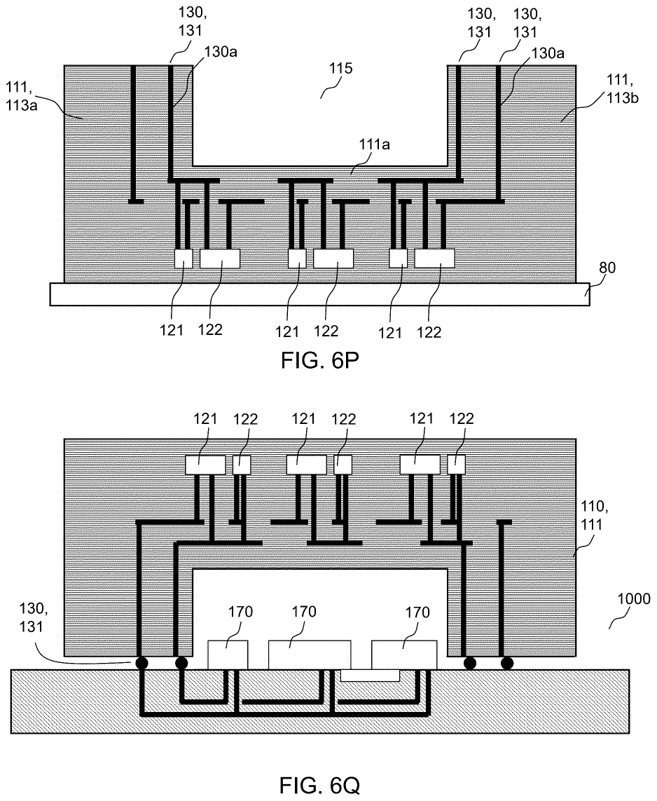

FIG. 6A to FIG. 6Q show an example process of making the device 110 and the assembly 1000, according to various aspects.

According to various aspects, with reference to FIG. 6A, the process (or method) may include providing or disposing material (e.g. a first layer of the material) for the main body 111 (herein referred to as “main-body material 111a”) on (e.g. directly on) a surface of a carrier 80. According to various aspects, this may correspond to or may be referred to as material (e.g. mold) shaping on the carrier 80. According to various aspects, the main-body material 111a may include an organic mold compound (e.g. polymer-based material), a polymer or polymer composite, epoxy resin (e.g. with silica filler), polyester resin, polyethylene, polypropylene, thermoplastics, ceramic-based material, or any other suitable material or material composite.

According to various aspects, with reference to FIG. 6B, the process (or method) may include (e.g. further include) providing or disposing at least one power management component 121 and/or at least one passive component 122 on (e.g. directly on) the main-body material 111a that is on the carrier 80. Thus, the at least one power management component 121 and/or the at least one passive component 122 may be on a surface of the main-body material 111a that faces away from the carrier 80. According to various aspects, this may be performed after or subsequent to providing the main-body material 111a on the surface of the carrier 80.

According to various aspects, with reference to FIG. 6C, the process (or method) may include (e.g. further and/or subsequently include) encapsulating the at least one power management component 121 and/or the at least one passive component 122 with the main-body material 111a. For example, a second layer of the main-body material 111a may be disposed over the first layer of the main-body material 111a as well as over the at least one power management component 121 and/or the at least one passive component 122. Accordingly, the at least one power management component 121 and/or the at least one passive component 122 may be encased within the main-body material 111a.

According to various aspects, with reference to FIG. 6D, the process (or method) may include (e.g. further and/or subsequently include) forming at least one hole or unfilled via in the main-body material 111a to expose at least a portion of the at least one power management component 121 and/or the at least one passive component 122. Specifically, a first end of the at least one unfilled via may be at the at least one power management component 121 and/or the at least one passive component 122, while an opposite second end of the at least one unfilled via may be at a surface of the main-body material 111a that faces away from the carrier 80. According to various aspects, the unfilled via may be formed, for example, by drilling (e.g. laser drill or mechanical drill) the main-body material 111a.

According to various aspects, with reference to FIG. 6E, the process (or method) may include (e.g. further and/or subsequently include) filling the at least one unfilled via with a conductive material (e.g. copper) 130a. Additionally, with reference to FIG. 6F, the process (or method) may include providing or depositing a layer of the conductive material 130a on the surface of the main-body material 111a that faces away from the carrier 80. According to various aspects, this may be carried out using a plating process, such as electroplating or electroless copper plating, for forming conductive path(s) through the at least one via and on the surface of the main-body material 111a.

According to various aspects, with reference to FIG. 6G, the process (or method) may include (e.g. further and/or subsequently include) removing one or more regions of the conductive material 130a from the surface of the main-body material 111a that faces away from the carrier 80. According to various aspects, this may involve etching selected region(s) of the conductive material 130a from the surface of the main-body material 111a to form the conductive path(s).

According to various aspects, with reference to FIG. 6H, the process (or method) may include (e.g. further and/or subsequently include) encapsulating the conductive path(s) with more main-body material 111a. For instance, a third layer of the main-body material 111a may be disposed over the second layer of the main-body material 111a as well as the conductive path(s).

According to various aspects, with reference to FIG. 6I, the process (or method) may include (e.g. further and/or subsequently include) forming at least one hole or unfilled via in the main-body material 111a to expose at least another portion of the at least one power management component 121 and/or the at least one passive component 122. Specifically, a first end of these at least one unfilled via may be at the at least one power management component 121 and/or the at least one passive component 122, while an opposite second end of these at least one unfilled via may be at a surface of the main-body material 111a that faces away from the carrier 80.

According to various aspects, with reference to FIG. 6J, the process (or method) may include (e.g. further and/or subsequently include) filling the at least one unfilled via with the conductive material (e.g. copper) 130a. Additionally, with reference to FIG. 6K, the process (or method) may include providing or depositing another layer of the conductive material 130a on the surface of the main-body material 111a that faces away from the carrier 80. According to various aspects, this may be carried out using a plating process, such as electroplating or electroless copper plating, for forming further conductive path(s) through the at least one via and on the surface of the main-body material 111a.

According to various aspects, with reference to FIG. 6L, the process (or method) may include (e.g. further and/or subsequently include) removing one or more regions of the conductive material 130a from the surface of the main-body material 111a that faces away from the carrier 80. According to various aspects, this may involve etching selected region(s) of the conductive material 130a from the surface of the main-body material 111a to form the further conductive path(s).

According to various aspects, with reference to FIG. 6M, the process (or method) may include (e.g. further and/or subsequently include) encapsulating the further conductive path(s) with more main-body material 111a. For instance, a further (e.g. fourth) layer of the main-body material 111a may be disposed over a previously exposed layer (e.g. the third layer) of the main-body material 111a as well as the further conductive path(s).

According to various aspects, with reference to FIG. 6N, the process (or method) may include (e.g. further and/or subsequently include) forming at least one hole or unfilled via in the main-body material 111a to expose at least a portion of the conductive path(s) and/or the further conductive path(s). Specifically, a first end of the at least one unfilled via may be at the conductive path(s) and/or the further conductive path(s), while an opposite second end of the at least one unfilled via may be at a surface of the main-body material 111a that faces away from the carrier 80.

According to various aspects, with reference to FIG. 6O, the process (or method) may include (e.g. further and/or subsequently include) filling the at least one unfilled via with the conductive material (e.g. copper) 130a. Accordingly, conductive material 130a at the second end of the via (i.e. at the surface of the main-body material 111a that faces away from the carrier 80) may be electrically connected to the at least one power management component 121 and/or the at least one passive component 122. According to various aspects, the device-interconnect 130 may include or may be composed of the conductive material 130a. According to various aspects, the conductive material 130a at the second end of the at least one via may correspond to (in other words, may serve as or may be) auxiliary connection point(s) 131 of the device-interconnect 130, while conductive material at the at least one power management component 121 and/or the at least one passive component 122 (e.g. at the first end of the vias) may correspond to primary connection point(s) of the device-interconnect 130. According to various aspects, an exposed surface of the main-body material 111a that faces away from the carrier 80 may be substantially free of conductive material 130a other than where the second end of the at least one via is located (e.g. by removing any excess conductive material 130a and/or excess main-body material 111a, for instance, using a grinding or mechanical grinding process, or a polishing process, etc.).

According to various aspects, with reference to FIG. 6P, the process (or method) may include (e.g. further and/or subsequently include) removing at least one portion of the main-body material 111a from a surface of the main-body material 111a that faces away from the carrier 80 to form at least one die-receiving-space 115. As an example, shown in FIG. 6P, the removed portion of the main-body material 111a may be a central segment portion that is between a pair of opposite end segment portions 113a, 113b of the main-body material 111a. As another example, according to various other aspects, the removed portion of the main-body material 111a may be a central portion surrounded or bounded by a peripheral edge portion of the main-body material 111a. According to various aspects, a depth of the removed portion of the main-body material 111a may correspond to the height (i.e. along the z-axis) of the die-receiving-space 115. According to various aspects, the at least one portion of the main-body material 111a may be removed via etching or any other suitable technique.

According to various other aspects, the process (or method) may include (e.g. further and/or subsequently include) removing at least one other portion of the main-body material 111a to form at least one ventilation opening 116 (as shown in FIG. 2C). As an example, the ventilation opening 116 may be formed after the formation of the at least one die-receiving-space 115. According to various aspects, the at least one other portion of the main-body material 111a may be removed via etching or any other suitable technique.

According to various aspects, with reference to FIG. 6Q, the process (or method) may include (e.g. further and/or subsequently include) removing or separating the carrier 80 from the main-body material 111a.

According to various aspects, with reference to FIG. 6Q, the process (or method) may include (e.g. further and/or subsequently include) attaching or coupling the device 110 to the substrate 150 to form the assembly 1000. In particular, the process (or method) may include electrically coupling the auxiliary connection point(s) 131 of the device-interconnect 130 to the connection point(s) of the substrate-interconnect 160 (e.g. via solder bump(s) or any other suitable element). Specifically, the auxiliary connection point(s) 131 of the device-interconnect 130 and the connection point(s) of the substrate-interconnect 160 may be directed towards and/or interfacing each other within the assembly 1000.

According to various aspects, at least one die 170 may be provided or mounted on the substrate 150 before attaching or coupling the device 110 to the substrate 150. According to various aspects, the at least one die 170 may be electrically coupled or connected to the connection point(s) of the substrate-interconnect 160.

According to various aspects, any of the steps of the process (or method) described herein may be performed sequentially or interchanged with one another where applicable.

Various aspects have thus described a device that enhances power management and thermal efficiencies in semiconductor assemblies.

Additionally, the modular nature of the device enables flexible placement on a substrate, optimizing space utilization and encouraging the creation of more compact and high-performance assemblies.

Furthermore, the thermal dissipation features associated with the device ensures reliable operation and longevity of any assembly or system, making the device an ideal solution for the increasing demands of modern electronic devices.

While the disclosure has been particularly shown and described with reference to specific aspects, it should be understood by those skilled in the art that various changes, modification, and variation in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

To more readily understand and put into practical effect the present device, assembly, and method, they will now be described by way of examples. For the sake of brevity, duplicate descriptions of features and properties may be omitted.

Example 1 provides a device. The device may include a main body having a panel portion and a protrusion arrangement extending from the panel portion, the protrusion arrangement being non-parallel to the panel portion. The device may further include at least one power management component disposed at the panel portion of the main body. The device may further include an interconnect including a primary connection point and an auxiliary connection point, for which, the primary connection point may be electrically coupled to the at least one power management component at the panel portion of the main body, while the auxiliary connection point may be positioned away from the panel portion.

Example 2 may include the system of example 1 and/or any other example disclosed herein, for which, the protrusion arrangement of the main body may be perpendicular to the panel portion of the main body.

Example 3 may include the system of example 1 and/or any other example disclosed herein, for which, the protrusion arrangement may include a plurality of protrusion members extending from a same side of the panel portion, the plurality of protrusion members being spaced apart from one another and, for which, an inner surface of the panel portion as well as inner surfaces of the plurality of protrusion members define a space adapted to accommodate at least one die.

Example 4 may include the system of example 3 and/or any other example disclosed herein, for which, the auxiliary connection point of the interconnect may extend or reach into the space.

Example 5 may include the system of example 1 and/or any other example disclosed herein, for which, the auxiliary connection point of the interconnect may be at a longitudinal free end or longitudinal end surface of the protrusion arrangement, positioned distally to the panel portion.

Example 6 may include the system of example 1 and/or any other example disclosed herein, for which, the at least one power management component may include at least a voltage regulator. Accordingly, the device may be a voltage regulator module.

Example 7 may include the system of example 6 and/or any other example disclosed herein, for which, the device may further include at least one passive component electrically coupled to the at least one power management component and, for which, the at least one passive component may be disposed at the panel portion of the main body.

Example 8 may include the system of example 7 and/or any other example disclosed herein, for which, the at least one passive component may include at least one of an amplifier, a resistor, a transistor, and/or a capacitor.

Example 9 may include the system of example 1 and/or any other example disclosed herein, for which, the main body may include or may be composed of a rigid and/or electrically non-conductive material.

Example 10 provides an assembly. The assembly may include a substrate and a device (e.g. the device of example 1 and/or any other example disclosed herein) disposed on the substrate. The device may include a main body which may include a panel portion and a protrusion arrangement extending from the panel portion, the protrusion arrangement being non-parallel to the panel portion, for which, the protrusion arrangement may be disposed on a surface of the substrate in a manner which spaces (or so as to space) the panel portion apart from the surface of the substrate. The device may further include at least one power management component disposed at the panel portion of the main body. The device may further include an interconnect that may include a primary connection point and an auxiliary connection point, for which, the primary connection point may be electrically coupled to the at least one power management component at the panel portion of the main body, while the auxiliary connection point may be positioned away from the panel portion.

Example 11 may include the system of example 10 and/or any other example disclosed herein, for which, the assembly may further include at least one die disposed on the surface of the substrate, such that the at least one die is between the substrate and the panel portion of the main body, for which the auxiliary connection point of the interconnect of the device may be electrically coupled to the at least one die.

Example 12 may include the system of example 11 and/or any other example disclosed herein, for which, the at least one die may include at least a central processing unit, a system-on-chip, a graphic processing unit, a neural network processing unit, a tensor processing unit, and/or a high-bandwidth memory.

Example 13 may include the system of example 11 and/or any other example disclosed herein, for which, the assembly may further include a heat-dissipation arrangement thermally coupled to the at least one die and, for which, the panel portion of the main body of the device may include at least one through-hole (e.g. ventilation opening) at the panel portion of the main body.

Example 14 may include the system of example 13 and/or any other example disclosed herein, for which, at least a segment of the heat-dissipation arrangement may be within the through-hole at the panel portion of the main body.

Example 15 may include the system of example 13 and/or any other example disclosed herein, for which, the heat-dissipation arrangement may include a thermally conductive plug or a heat sink.

Example 16 may include the system of example 10 and/or any other example disclosed herein, for which, at least a segment of the interconnect of the device may be embedded within the protrusion arrangement of the main body of the device.

Example 17 may include the system of example 10 and/or any other example disclosed herein, for which, at least a segment of the interconnect of the device may protrude or extend from the panel portion into a space between the panel portion and the surface of the substrate.

Example 18 provides a method. The method may include providing a main body with a panel portion and a protrusion arrangement extending from the panel portion, the protrusion arrangement being non-parallel to the panel portion. The method may further include disposing at least one power management component at the panel portion of the main body. The method may further include providing an interconnect including a primary connection point and an auxiliary connection point. The method may further include electrically coupling the primary connection point of the interconnect to the at least one power management component at the panel portion of the main body. The method may further include positioning the auxiliary connection point away or apart from the panel portion of the main body.

Example 19 may include the system of example 18 and/or any other example disclosed herein, for which, the method may further include disposing the protrusion arrangement of the main body on a surface of a substrate, with the panel portion of the main body spaced apart from the surface of the substrate.

Example 20 may include the system of example 19 and/or any other example disclosed herein, for which, the method may further include disposing at least one die on the surface of the substrate, with the at least one die between the substrate and the panel portion of the main body. The method may further include electrically coupling the auxiliary connection point of the interconnect to the at least one die.

In a further example, any one or more of examples 1 to 20 may be combined.

1. A device comprising:
a main body comprising:
a panel portion, and
a protrusion arrangement extending from the panel portion, the protrusion arrangement being non-parallel to the panel portion;
at least one power management component disposed at the panel portion of the main body; and
an interconnect comprising a primary connection point and an auxiliary connection point, wherein the primary connection point is electrically coupled to the at least one power management component at the panel portion of the main body, while the auxiliary connection point is positioned away from the panel portion.

2. The device of claim 1,
wherein the protrusion arrangement of the main body is perpendicular to the panel portion of the main body.

3. The device of claim 1,
wherein the protrusion arrangement comprises a plurality of protrusion members extending from a same side of the panel portion, the plurality of protrusion members being spaced apart from one another;
wherein an inner surface of the panel portion as well as inner surfaces of the plurality of protrusion members define a space adapted to accommodate at least one die.

4. The device of claim 3,
wherein the auxiliary connection point of the interconnect extends into the space.

5. The device of claim 1,
wherein the auxiliary connection point of the interconnect is at a longitudinal free end of the protrusion arrangement.

6. The device of claim 1,
wherein the at least one power management component comprises at least a voltage regulator.

7. The device of claim 6, further comprising:
at least one passive component electrically coupled to the at least one power management component,
wherein the at least one passive component is disposed at the panel portion of the main body.

8. The device of claim 7,
wherein the at least one passive component comprises at least one of an amplifier, a resistor, a transistor, or a capacitor.

9. The device of claim 1,
wherein the main body is composed of a rigid and electrically non-conductive material.

10. An assembly comprising:
a substrate;
a device disposed on the substrate, the device comprising:
a main body comprising a panel portion and a protrusion arrangement extending from the panel portion, the protrusion arrangement being non-parallel to the panel portion, wherein the protrusion arrangement is disposed on a surface of the substrate in a manner which spaces the panel portion apart from the surface of the substrate,
at least one power management component disposed at the panel portion of the main body, and
an interconnect comprising a primary connection point and an auxiliary connection point, wherein the primary connection point is electrically coupled to the at least one power management component at the panel portion of the main body, while the auxiliary connection point is positioned away from the panel portion.

11. The assembly of claim 10, further comprising:
at least one die disposed on the surface of the substrate, the at least one die being between the substrate and the panel portion of the main body,
wherein the auxiliary connection point of the interconnect of the device is electrically coupled to the at least one die.

12. The assembly of claim 11,
wherein the at least one die comprises at least a central processing unit, a system-on-chip, a graphic processing unit, a neural network processing unit, a tensor processing unit, or a high-bandwidth memory.

13. The assembly of claim 11, further comprising:
a heat-dissipation arrangement thermally coupled to the at least one die,
wherein the panel portion of the main body of the device comprises at least one through-hole at the panel portion of the main body.

14. The assembly of claim 13,
wherein at least a segment of the heat-dissipation arrangement is within the through-hole at the panel portion of the main body.

15. The assembly of claim 13,
wherein the heat-dissipation arrangement comprises a thermally conductive plug or a heat sink.

16. The assembly of claim 10,
wherein at least a segment of the interconnect of the device is embedded within the protrusion arrangement of the main body of the device.

17. The assembly of claim 10,
wherein at least a segment of the interconnect of the device protrudes from the panel portion into a space between the panel portion and the surface of the substrate.

18. A method comprising:
providing a main body with a panel portion and a protrusion arrangement extending from the panel portion, the protrusion arrangement being non-parallel to the panel portion;
disposing at least one power management component at the panel portion of the main body;
providing an interconnect comprising a primary connection point and an auxiliary connection point;
electrically coupling the primary connection point of the interconnect to the at least one power management component at the panel portion of the main body; and
positioning the auxiliary connection point away from the panel portion of the main body.

19. The method of claim 18, further comprising:
disposing the protrusion arrangement of the main body on a surface of a substrate, with the panel portion of the main body spaced apart from the surface of the substrate.

20. The method of claim 19, further comprising:
disposing at least one die on the surface of the substrate, with the at least one die between the substrate and the panel portion of the main body; and
electrically coupling the auxiliary connection point of the interconnect to the at least one die.
